(19) United States
(12) Patent Application Publication
(10) Pub. No.: US 2009/0027057 A1
(43) Pub. Date: Jan. 29, 2009

(54) Ethernet Electrometer

(76) Inventors: John T. Anderson, Elburn, IL (US); Patrick DeLurgio, Darien, IL (US); Randy Alkire, Romeoville, IL (US); Michael Molitsky, Plainfield, IL (US)

Correspondence Address: FOLEY & LARDNER LLP, 150 EAST GILMAN STREET, P.O. BOX 1497, MADISON, WI, 53701-1497, US

(21) Appl. No.: 11/828,941

(22) Filed: Jul. 26, 2007

(51) Int. Cl. G01R 29/12

(52) U.S. Cl. 324/457

(57) ABSTRACT

An electrometer includes an input terminal adapted to receive an input signal an ethernet terminal, a web server, and a microcontroller. The ethernet terminal is adapted to receive an ethernet cable such that electrical power is provided to the ethernet terminal. The web server is in electrical communication with the ethernet terminal, and is adapted to receive a command. The microcontroller is in electrical communication with at least one of the ethernet terminal and the web server, and is adapted to execute the received command.

The United States Government has rights in this invention pursuant to Contract No. W-31-109-ENG-38 between the United States Government and The University of Chicago and/or pursuant to Contract No. DE-AC02-06CH11357 between the United States Government and UChicago Argonne, LLC representing Argonne National Laboratory.

The subject of the disclosure relates generally to an electrometer device for measuring an electrical signal. More specifically the disclosure relates to an electrometer device which is adapted to receive power over Ethernet (PoE) through an Ethernet cable. The electrometer device can also send and receive data through the Ethernet cable such that the electrometer is remotely controlled. The electrometer device can be a modular device which includes a motherboard and an interchangeable daughterboard. The interchangeable daughterboard allows the electrometer device to be adapted for use in a plurality of diverse applications.

### BACKGROUND

An electrometer is a highly sensitive instrument that is generally designed to measure small quantities of voltage, charge, resistance, current, etc. Electrometers can be either mechanical or electronic in nature. Mechanical electrometers rely on mechanical forces associated with electrostatic fields to measure an analog signal. Electronic electrometers generally utilize some form of electronic amplifier which allows the electrometer to detect and monitor a wide range of analog signals. In recent years, electronic electrometers have become more prevalent because of their ability to detect and monitor extremely minute analog signals Electrometers are used in a wide array of applications to measure a wide array of analog signals, including emitted radiation, a current generated when an x-ray passes through a photodiode, a current produced by a photodiode when struck by light, etc.

Traditional electronic electrometers include a standard electrical cord and plug, and operate by receiving electrical power through a standard power outlet. As such, electronic electrometers can only be used in locations in which there is access to a power outlet. In some instances, an extension cord may be used to position an electrometer within a limited distance of the power outlet. However, extension cords can be burdensome, expensive, and even potentially hazardous in a scientific laboratory or other work environment. With or without an extension cord, the electrical cord of an electronic electrometer is one of many input/output lines connected to the electronic electrometer. This large number of cords and cables results in cluttered work areas.

Traditional electrometers are also static in nature such that none of an electrometer's components are interchangeable. As such, users may be required to have a plurality of different electrometers for different tasks. For example, a first electrometer with a first amplifier may be required for ideal measurement of a first analog signal, and a second electrometer with a second amplifier may be required for ideal measurement of a second analog signal. As electrometers can range in price anywhere from $6000 to over $10,000, the need to purchase multiple electrometers can be extremely cost prohibitive. Traditional electrometers are further limited in their ability to be controlled remotely. As such, users are required to approach the electrometer to adjust its settings. This can be harmful to the user if the electrometer is being used to gather data in an area in which there is radiation, fumes, or otherwise adverse conditions.

Traditional electrometers are also limited in their ability to accurately measure analog signals because of inadequate amplification, inadequate resolution, inadequate measurement rates, and inadequate filtering of the analog input signal. For example, a typical high end electrometer may only have a few fixed gain ranges with a full scale current ranging from 2 nano-Amps to 2 milli-Amps, a resolution of only 14 bits (or 1 part in 20,000), a sample rate of only 1 sample every 300 milli-seconds, and fixed filtering of the analog signal with the corner frequency dependent upon the amplification range selected. Further, traditional electrometers are bulky and require a plurality of additional components. A traditional electrometer system may include a signal processing device, a signal conditioning device, a communication device, an interface device, a control device, a local computing device, an external display, etc. As such, electrometer systems can be extremely expensive.

Thus, there is a need for an electrometer which does not include a standard power cord and which does not require a standard power outlet to receive power. Further, there is a need for an electrometer which can be remotely adjusted such that users are shielded from adverse conditions in proximity to the electrometer. Further, there is a need for an electrometer with interchangeable components such the electrometer can be used for more than a single application. Further, there is a need for an electrometer with the ability to accurately measure a wide range of signals. Further yet, there is a need for a compact, inexpensive electrometer system.

### SUMMARY

An exemplary electrometer includes an input terminal adapted to receive an input signal, an ethernet terminal, a web server, and a microcontroller. The ethernet terminal is adapted to receive an ethernet cable such that electrical power is provided to the ethernet terminal. The web server is in electrical communication with the ethernet terminal, and is adapted to receive a command. The microcontroller is in electrical communication with at least one of the ethernet terminal and the web server, and is adapted to execute the received command.

Another exemplary electrometer includes an interchangeable daughterboard and a motherboard in electrical communication with the interchangeable daughterboard. The interchangeable daughterboard includes an input terminal adapted to receive an input signal. The motherboard includes an ethernet terminal, a web server, and a microcontroller. The ethernet terminal is adapted to receive an ethernet cable through which information is received. The web server is in electrical communication with the ethernet terminal, and is adapted to receive a command. The microcontroller, which includes a program corresponding to the interchangeable daughterboard, is configured to execute the received command.

An exemplary electrometer system includes an electrometer and a remote computer The electrometer includes an input terminal adapted to receive an input signal, an ethernet terminal adapted to receive an ethernet cable through which electrical power is received, and a web server in electrical communication with the ethernet terminal and adapted to receive a command. The remote computer is in communication with the web server, and is adapted to provide the command to the web server.

Other principal features and advantages will become apparent to those skilled in the art upon review of the following drawings, the detailed description, and the appended claims.

### BRIEF DESCRIPTION OF THE DRAWINGS

Exemplary embodiments will hereafter be described with reference to the accompanying drawings.

FIG. 1 is a top view of an Ethernet electrometer in accordance with an exemplary embodiment.

FIG. 2 is a block diagram illustrating an interior of the Ethernet electrometer of FIG. 1 in accordance with an exemplary embodiment.

FIG. 3 depicts an Ethernet electrometer system in accordance with an exemplary embodiment.

### DETAILED DESCRIPTION

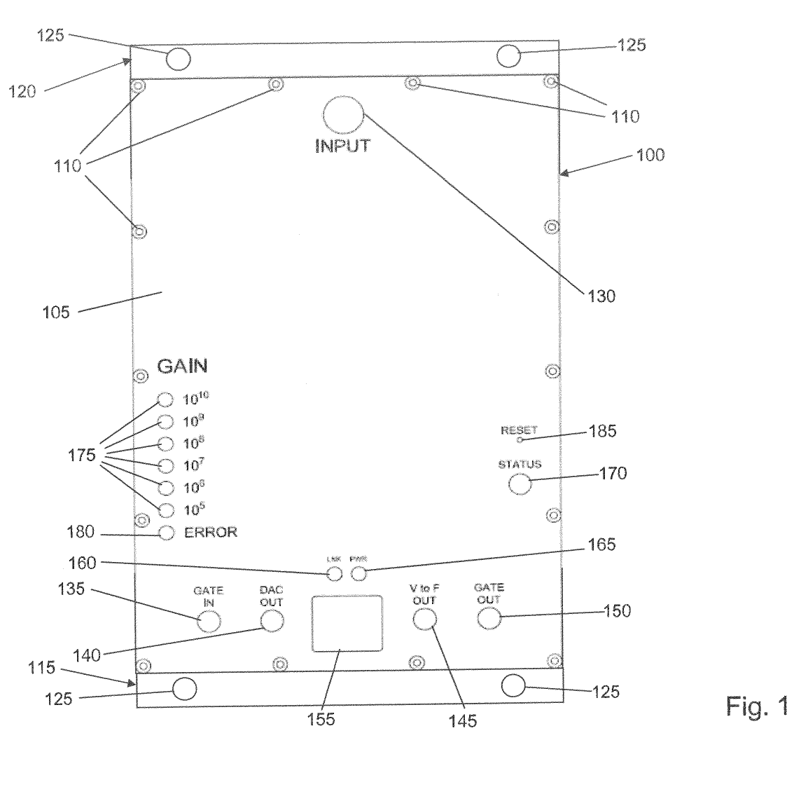

FIG. 1 is a top view of an Ethernet electrometer 100 in accordance with an exemplary embodiment. Ethernet electrometer 100 includes a top plate 105 and a plurality of side walls (not shown) mounted to a bottom plate (not shown) to form a rectangular box. As used in this disclosure, the term “mount” can include join, unite, connect, associate, insert, hang, hold, affix, attach, fasten, bind, paste, secure, bolt, nail, glue, screw, rivet, solder, weld, and other like terms. In an exemplary embodiment, Ethernet electrometer 100 can have dimensions of approximately 4″×6″×1.38″. Alternatively, Ethernet electrometer 100 can have any other dimensions and/or can take on any other shape including circular, square, etc. Top plate 105 of Ethernet electrometer 100 is mounted to the plurality of side walls with a plurality of fasteners 110. Fasteners 110 can be screws, rivets, or any other type of fasteners. In alternative embodiments, top plate 105 can be mounted to the plurality of side walls through one or more latches or catches, one or more hinges, or by any other method known to those skilled in the art.

Ethernet electrometer 100 includes a lower mounting flange 115 and an upper mounting flange 120 such that Ethernet electrometer 100 can be securely mounted to a surface. Lower mounting flange 115 and upper mounting flange 120 each include mounting holes 125 adapted to receive screws, nails, bolts, or other mounting fasteners. Depending on the application, it may be desirable to mount or otherwise place Ethernet electrometer 100 in a location proximate to other electronic equipment. In an exemplary embodiment, Ethernet electrometer 100 can be radio frequency shielded (RF-shielded) to help prevent interference from electromagnetic signals in the vicinity of Ethernet electrometer 100. The RF-shielding can be imparted using any shielding material and/or any shielding method known to those of skill in the art.

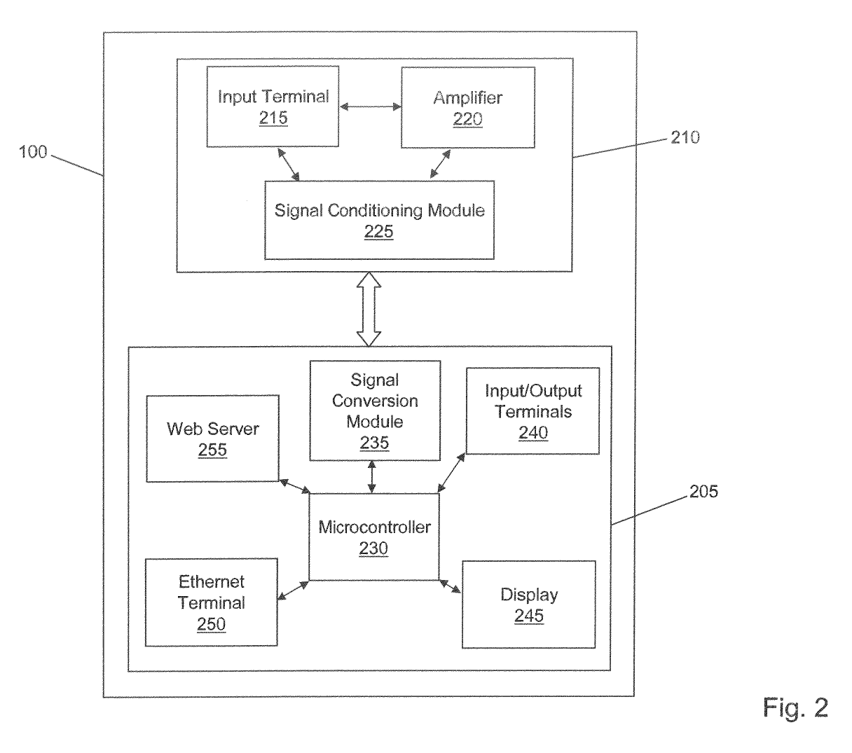

Ethernet electrometer 100 also includes a plurality of input and output terminals which can be connected to input/output lines (not shown) such that signals can be sent and received by Ethernet electrometer 100. In an exemplary embodiment, any or all of the inputs/outputs of Ethernet electrometer 100 can include coaxial connectors such as LEMO connectors, Bayonet Neill-Concelman (BNC) connectors, etc. The motherboard of Ethernet electrometer 100, which is described in more detail with reference to FIG. 2, can include pin and socket connections configured to accommodate any type of connectors. As such, Ethernet electrometer 100 can be configured for use in a plurality of distinct applications.

Ethernet electrometer 100 includes an input terminal 130 adapted to receive an input signal. In alternative embodiments, Ethernet electrometer 100 can include any other number of inputs, including two, three, four, etc. In an exemplary embodiment, input terminal 130 can be mounted to an interchangeable daughterboard which can be removed and replaced such that Ethernet electrometer 100 is optimally adapted for a particular application. The interchangeable daughterboard is described in more detail with reference to FIG. 2. In another exemplary embodiment, input terminal 130 can receive an input line (not shown) such as a coaxial cable through which the input signal is conveyed. The input line can include one or more clips, clamps, wires, probes, sensors, etc. adapted to be connected to a source of the input signal. The input line may also include a ground such that Ethernet electrometer 100 can be grounded to earth. Alternatively, Ethernet electrometer can be grounded through a ground terminal or by any other method known to those of skill in the art.

In an exemplary embodiment, Ethernet electrometer 100 can include galvanically isolated power conversion circuits such that circuitry within Ethernet electrometer 100 is galvanically isolated from ground. As such, Ethernet Electrometer 100 can be “floated” or otherwise referenced to an installation ground other than earth. In one embodiment, input terminal 130 and/or the input line may include coaxial or shielded, twisted pair connectors such as those manufactured by LEMO Kings, AMP, ODU, Amphenol, etc. If a shielded, twisted pair connector is used, the twisted pair can be connected to a sensor element and the shield drain can be connected to the ground of Ethernet electrometer 100. Alternatively, any other type of connector(s) may be used.

A gate in terminal 135 can receive a logic signal from an external source to control Ethernet electrometer 100 based upon the settings of Ethernet electrometer 100. For example, the logic signal received through gate in terminal 135 can be used by Ethernet electrometer 100 to make time-gated measurements. A voltage output terminal 140 can be used to provide an analog output voltage signal which is proportional to the input signal received at input terminal 130. The analog output voltage signal can be provided to a local computing device for monitoring and/or storage. Alternatively, the analog output voltage signal may be used to control a local device or synchronize a local device with the input signal.

A frequency output terminal 145 can be used to provide an output signal with a frequency proportional to the input signal and/or the analog output voltage signal provided through voltage output terminal 140. In one embodiment, the output signal from frequency output terminal 145 can be used to interface Ethernet electrometer 100 with a beam position control circuit as known to those of skill in the art. A gate out terminal 150 can be used to output a logic signal based upon a value of the input signal received through input terminal 130. The logic signal from gate out terminal 150 may be used to indicate that the analog input signal is above or below a user-defined threshold. The logic signal may also act as a comparator which can be used for time-of-flight synchronization as known to those of skill in the art. In alternative embodiments, Ethernet electrometer 100 may include any other analog and/or digital inputs and outputs.

In an exemplary embodiment, frequency output terminal 145 may be connected to external electronics which are adapted to modify magnet currents in a way proportionate to the frequency provided by Ethernet electrometer 100 such that beam position is maintained. Similarly, voltage output terminal 140 may be connected to external electronics which are adapted to modify magnet currents in a way proportionate to the voltage provided by Ethernet electrometer 100 such that beam position is maintained. In one embodiment, a plurality of Ethernet electrometers (or a single Ethernet electrometer with multiple input/output channels), may be used with a set of detectors surrounding a beam pipe to provide continuous correction of beam position in multiple axes. Signals output from Ethernet electrometer 100 may also be connected to data logging equipment or data acquisition computers external to Ethernet Electrometer 100.

An Ethernet terminal 155 can be adapted to receive an Ethernet cable (not shown). In an exemplary embodiment, Ethernet electrometer 100 can use Ethernet terminal 155 to send and/or receive data to/from a remote destination. For example, Ethernet electrometer 100 can be located at a first location and a user can be located at a second location any distance from Ethernet electrometer 100. The user can use a computer or other communication device to send commands, change settings adjust the gain, and otherwise control Ethernet electrometer 100 through Ethernet terminal 155. In an exemplary embodiment, Ethernet terminal 155 may be connected to a network such that control and monitoring of Ethernet electrometer 100 can take place at any network accessible location. Alternatively, Ethernet terminal 155 may be wired directly to a computing device which may be thousands of feet from Ethernet electrometer 100.

In another exemplary embodiment Ethernet terminal 155 can also be used to provide power to Ethernet electrometer 100. Power can be provided through Ethernet terminal 155 using technology known as power over Ethernet (PoE). The PoE can be provided to Ethernet electrometer 100 in accordance with the IEEE 802.3af specification as known to those skilled in the art. Alternatively, the PoE can be provided to Ethernet electrometer 100 according to any other specification or method presently known or developed in the future. For example, it may someday be desirable for Ethernet electrometer 100 to receive PoE in accordance with the IEEE 802.3at standard which is still under development. In an exemplary embodiment, both data exchange and provision of PoE can occur through Ethernet terminal 155. However, in some cases PoE may not be available through the Ethernet connection used for data exchange. In such cases, Ethernet electrometer 100 may include a separate stand-alone Ethernet terminal for providing PoE. In another exemplary embodiment Ethernet electrometer 100 may also include a secondary power supply input adapted to receive a power cord such that Ethernet electrometer 100 can receive power through a standard electrical outlet.

Providing power to Ethernet electrometer 100 through an Ethernet cable allows Ethernet electrometer 100 to be used virtually anywhere. Traditional electrometers are restricted because they can only be used in close proximity to a power outlet. With PoE technology, Ethernet electrometer 100 can be used in excess of 1000 feet from an Ethernet hub. Further, providing both data exchange and power through a single cable reduces the number of cables running to/from Ethernet electrometer, resulting in a less cluttered and safer work environment.

In an exemplary embodiment, Ethernet electrometer 100 can operate on just a fraction of the electrical power that is received through Ethernet terminal 155. As such, Ethernet electrometer 100 can use excess electrical power to supply a bias voltage, power, etc. to a sensor circuit external to Ethernet electrometer 100. For example, a programmable bias voltage may be provided at input terminal 130 such that power is conveyed to a photodiode sensor in electrical communication with Ethernet electrometer 100. As such, Ethernet Electrometer 100 and the photodiode sensor can be a fully self-contained remote data acquisition system that requires no additional power connections. As another example, Ethernet Electrometer 100 may use excess electrical energy to power a high voltage, low current power supply such that power can be provided to a photomultiplier tube. By correct selection of the photomultiplier tube and a scintillator crystal, Ethernet electrometer 100 can be used as an area radiation detector at public venues, portals, etc. In one embodiment, because of its small size and low power requirements, Ethernet electrometer 100 can be concealed in a briefcase or other small container along with a wireless PoE hub which may be powered from a battery. This allows Ethernet electrometer 100 to be used as an inconspicuous detector device. In alternative embodiments, Ethernet electrometer 100 can provide power to any other type(s) of sensors.

Ethernet electrometer 100 also includes a plurality of indicators. In an exemplary embodiment, the indicators can include one or more light emitting diodes (LEDs) which can be illuminated based on the status of Ethernet electrometer 100. Alternatively, any other type of light source(s) may be used for the indicators. In another exemplary embodiment, illumination of the indicators can be controlled by a microcontroller which is described in more detail with reference to FIG. 2. A link indicator 160 can be used to indicate whether Ethernet electrometer 100 is connected to an Ethernet hub or port. A power indicator 165 can be used to indicate whether Ethernet electrometer 100 is receiving power. A status indicator 170 can be used to indicate the status of Ethernet electrometer 100. The status can include a normal operating mode, a programming mode, a testing or calibration mode, etc. Status indicator 170 may include a plurality of LEDs (or other light sources) of different colors to indicate different modes. Similarly, status indicator 170 may blink at one or more rates to indicate different modes.

A plurality of gain indicators 175 can be used to indicate an amount by which the input signal received through input terminal 130 is amplified. As illustrated with reference to FIG. 1, gain indicators 175 can be used to indicate gains in the ranges of 10⁵, 10⁶, 10⁷, 10⁸, 10⁹, and 10¹⁰ Volts/Amp. In alternative embodiments, amplification in other ranges may be provided. For example, gain indicators 175 may be used to indicate amplification ranging from 10⁴ Volts/Amp through 10¹¹ Volts/Amp. In an exemplary embodiment the gain can represent the gain of the analog output voltage signal from voltage output terminal 140 relative to the input signal received through input terminal 130. In another exemplary embodiment, the gain can have units of Volts/Amp. Alternatively, the gain can be measured according to any method. An error indicator 180 can be used to indicate that Ethernet electrometer 100 is not functioning properly. As such, error indicator 180 may be illuminated if the user selects a combination of control parameters which are not supported by Ethernet electrometer 100. Alternatively, error indicator 180 may be on if there is a problem reading the input signal, if there is a problem with internal circuitry, or if there is any other problem such that Ethernet electrometer 100 is not functioning properly.

In an exemplary embodiment, any or all of link indicator 160, power indicator 165, status indicator 170, gain indicators 175, and error indicator 180 may include one or more LEDs. As an example, link indicator 160 may include a single green LED which is lit whenever Ethernet electrometer 100 is connected to an Ethernet port. Power indicator 165 may include a green LED to indicate that Ethernet electrometer 100 is receiving power through Ethernet terminal 155, and an orange LED to indicate that Ethernet electrometer 100 is receiving power through a power cord plugged into an electrical outlet. In one embodiment, light patterns can be used to provide additional indications. For example, a predetermined number and/or pattern of gain indicators 175 may be illuminated if the user overrides normal fixed settings and enters user-defined parameters. Similarly, any or all of the indicators may blink at one or more rates to indicate modes, special conditions, errors, signal levels, etc.

Ethernet electrometer 100 also includes a reset 185. In an exemplary embodiment, reset 185 can include a hole in top plate 105 which is positioned directly over a recessed pushbutton switch. A user can insert a paper clip or other object through reset 185 to engage the recessed pushbutton switch and force a reset of an internal microcontroller of Ethernet electrometer 100. It is important to understand that Ethernet electrometer 100 is not limited to the features described with reference to FIG. 1. In alternative embodiments, Ethernet electrometer 100 may include additional, fewer, or different features. For example, Ethernet electrometer 100 may include additional inputs/outputs and/or additional indicators.

FIG. 2 is a block diagram illustrating components of Ethernet electrometer 100 in accordance with an exemplary embodiment. Additional, fewer, or different components may be included in alternative embodiments. Ethernet electrometer 100 includes a motherboard 205 and a daughterboard 210 in electrical communication with motherboard 205. As used herein, electrical communication can refer to any direct, indirect, wired, or wireless connection through which electrical signals can be conveyed. In an exemplary embodiment, daughterboard 210 can be an interchangeable circuit board such that Ethernet electrometer 100 can be optimally adapted for use in a variety of measurement and/or monitoring applications. For example, a first daughterboard may be used to optimally measure current from a first source and a second daughterboard may be used to optimally measure light from a second source.

Daughterboard 210 includes an input terminal 215 through which an input signal is received. Input terminal 215 can be the same as input terminal 130 described with reference to FIG. 1. The input signal can correspond to a measured voltage, current, resistance, pressure, radiation, light, or any other type of analog signal. In an exemplary embodiment, the input signal can be conveyed to input terminal 215 through an input line. The input line, which can be a cable, wire, or any other type of conducting line, can include a first end adapted to mate with input terminal 215 and a second end adapted to receive the input signal. The second end of the input line can include a wire, clip, a probe, a sensor, or any other device capable of receiving an analog input signal. As such, the input signal can be conveyed from the second end of the input line through the input line, through the first end of the input line, and into input terminal 215.

Daughterboard 210 also includes an amplifier 220. Amplifier 220 can be in electrical communication with input terminal 215 such that the input signal is able to be amplified. Input signal amplification may be desirable when extremely small analog signals are being measured. In an exemplary embodiment, amplifier 220 can have an adjustable gain ranging from approximately 10⁴ Volts/Amp to approximately 10¹¹ Volts/Amp, and which is adjustable in approximately 32,768 gain steps. In another exemplary embodiment, Ethernet electrometer 100 can be adapted to measure a full-scale current ranging from approximately 0.4 nano-Amps to approximately 40 micro-Amps. In alternative embodiments, a different gain range, a different number of gain steps, and/or a different full-scale current range may be provided. Amplifier 220 can respond to control signals from a microcontroller 230 mounted to motherboard 205. The gain, which can be indicated by gain indicators 175 described with reference to FIG. 1, can be locally or remotely controlled by a user of Ethernet electrometer 100.

Daughterboard 210 can also include a signal conditioning module 225 such that the input signal can be filtered or otherwise conditioned. Signal conditioning module 225 can include an analog filter and/or a digital filter. The filter(s) can be programmable and can be controlled by control signals from microcontroller 230 on motherboard 205. As such, a user can select a combination of programmable analog filtering and programmable digital filtering to obtain a desired tradeoff between update rate and resolution of the input signal. The input signal can be conditioned by signal conditioning module 225 before or after amplification by amplifier 220, depending on the embodiment. In alternative embodiments, signal conditioning module 225 can perform any other types of signal conditioning known to those of skill in the art. In another alternative embodiment, at least a portion of signal conditioning module 225 may be included on motherboard 205.

In an exemplary embodiment, daughterboard 210 can be mounted to or otherwise in electrical communication with motherboard 205 such that the input signal received through input terminal 215 is provided to motherboard 205. Daughterboard 210 can also receive commands and/or other information from motherboard 205. For example, based on local or remote user commands, microcontroller 230 can adjust the amount of gain provided by amplifier 220, the amount of analog filtering done by signal conditioning module 225, the amount of digital filtering done by signal conditioning module 225, and/or the amount of any other conditioning performed by signal conditioning module 225. Microcontroller 230 can also be used to adjust a sample rate at which the input signal is measured based on user commands. In an exemplary embodiment, the sample rate can be set anywhere from near direct current (DC) to approximately one sample every 12.5 microseconds. Alternatively, other sample rates may be provided.

Motherboard 205 includes microcontroller 230, a signal conversion module 235, input/output terminals 240, a display 245, an Ethernet terminal 250, and a web server 255. In alternative embodiments, motherboard 205 may include additional, fewer, or different components. Microcontroller 230 can be in electrical communication with each of the other components located on motherboard 205 such that all of the components of motherboard 205 are in at least indirect electrical communication with one another. Similarly, any or all of signal conversion module 235, input/output terminals 240, display 245, Ethernet terminal 250, and/or web server 255 may be in direct electrical communication with one other. For example, web server 255 may be in direct electrical communication with Ethernet terminal 250, and input/output terminals 240 may be in direct electrical communication with signal conversion module 235.

In an exemplary embodiment, microcontroller 230 can be any type of microcontroller (or microprocessor) known to those of skill in the art. Microcontroller 230 can be used to perform internal control functions of Ethernet electrometer 100. For example, microcontroller 230 can receive commands from a user, execute the commands, and control display 245 based on the executed commands. Microcontroller 230 can also include one or more signal processing algorithms based on the particular analog signal which is being measured. In an exemplary embodiment, microcontroller 230 can receive power from a power supply circuit (not shown) which is in communication with Ethernet terminal 250.

Microcontroller 230 can also be used to implement a self-test of Ethernet electrometer 100. The self-test can be used to ensure that Ethernet electrometer 100 is properly calibrated. The self-test can also be used (locally or remotely) to verify that Ethernet electrometer 100 is functional in all gain ranges. Microcontroller 230 can also include memory such that Ethernet electrometer 100 is equipped with an auto-recovery function. The auto-recovery function can be used to ensure that settings of Ethernet electrometer 100 are not lost during a power outage. Upon sensing a power failure, microcontroller 230 can store the current operating configuration of Ethernet electrometer 100 into a non-volatile memory. When power returns, microcontroller 230 can recall the stored operating configuration from the non-volatile memory such that Ethernet electrometer 100 is able to run at the previous settings. As such, once configured, Ethernet electrometer 100 can run autonomously until a change in settings is desired.

Signal conversion module 235 can include an analog-to-digital converter such that the signal received from daughterboard 210 can be represented in digital form. The digital form of the input signal can be output through gate out terminal 150 described with reference to FIG. 1. In an exemplary embodiment, signal conversion module 235 may include a 16-bit (1 part in 65,536) converter. Alternatively, any other type of converter known to those of skill in the art may be used. Signal conversion module 235 may also include a digital-to-analog converter, depending on the embodiment. In an alternative embodiment, at least a portion of signal conversion module 235 may be included on daughterboard 210.

Input/output terminals 240 can include gate in terminal 135, voltage output terminal 140, frequency output terminal 145, and/or gate out terminal 150 described with reference to FIG. 1. In alternative embodiments, other input and/or output terminals may be provided. For example, Ethernet electrometer 100 may be configured to provide a wide array of digital input/output functions including general parallel or serial input/output, limit switch sensing, motor control, power supply control, etc. Display 245 can include any or all of the indicators described with reference to FIG. 1. In alternative embodiments, other indicators may be provided. Microcontroller 230 can be used to control display 245 such that the appropriate indicators are illuminated. For example, if a user sets an amplifier gain in the range of 10⁷, microcontroller 230 can cause an LED (or other light source) corresponding to a gain of 10⁷ to be illuminated. Similarly, if microcontroller 230 detects an error, error indicator 180 described with reference to FIG. 1 can be illuminated.

Ethernet terminal 250 can be adapted to receive an Ethernet cable such that power over Ethernet (PoE) can be provided to Ethernet electrometer 100. In addition, Ethernet terminal 250 can be used to connect Ethernet electrometer 100 to a network or remote device such that data can be transferred to and from Ethernet electrometer 100. Data transferred to Ethernet electrometer through Ethernet terminal 250 can include commands, settings, modes, and other control information specified by a user. Data transferred from Ethernet electrometer 100 through Ethernet terminal 250 can include status information, display information, test data, input signal data, etc.

In an exemplary embodiment, web server 255 can be used by a user to remotely control Ethernet electrometer 100. Web server 255 can establish a web site, web portal, or other network location through which information can be exchanged between Ethernet electrometer 100 and a remote user device. Web server 255 can communicate through a network via an Ethernet cable attached to Ethernet terminal 250. The user can access the web site (or other network location) through a network browser as known to those of skill in the art. In an exemplary embodiment, the user can enter commands into his/her web browser, the commands can be conveyed to Ethernet electrometer 100 through Ethernet terminal 250, and microcontroller 230 can cause the commands to be executed. For example, the user may program Ethernet electrometer 100, set user-defined conditions, change the sample rate at which the analog signal is being measured, change the amount of analog and/or digital filtering done to the measured analog signal, adjust the gain of amplifier 220, etc.

Web server 255 can also provide the user with remote access to information regarding the input signal received through input terminal 215. For example, web server 255 can provide a value of the input signal, a digital representation of the input signal, a frequency representation of the input signal, an alert if the input signal exceeds a user-defined threshold, etc. In an exemplary embodiment, web server 255 can send/receive data through Ethernet terminal 250. The data can be sent/received directly to Ethernet terminal 250, or indirectly through microcontroller 230. Remote control and use of Ethernet electrometer 100 can be very beneficial when Ethernet electrometer 100 is placed at a hazardous or unstable location at which there is harmful radiation, fumes, pending natural disasters, or other dangers.

As described above daughterboard 210 can be interchangeable such that Ethernet electrometer 100 is a modular device. As such, Ethernet electrometer 100 can be reconfigured to perform a plurality of diverse functions. Different daughterboards can include different numbers and/or types of input terminals, different types of amplifiers, and/or different types of signal conditioning modules. Microcontroller 230 can be provided with different programs to accommodate the various daughterboards. For example, a first program can be downloaded onto microcontroller 230 when a first daughterboard is being used to measure a first analog signal and a second program can be downloaded onto microcontroller 230 when a second daughterboard is being used to measure a second analog signal. Similarly, web server 255 can be reprogrammed based on the daughterboard being used such that the web interface is accurate. In an alternative embodiment, a plurality of daughterboards may be used simultaneously in Ethernet electrometer 100 to measure a plurality of distinct analog signals. The plurality of daughterboards may be identical or different from one another, depending on the embodiment. In another alternative embodiment, a single daughterboard may include a plurality of input terminals such that a plurality of analog signals can be measured simultaneously.

In one embodiment, additional daughterboards and programming can be used to reconfigure Ethernet electrometer 100 into any number of compact network appliances. For example, Ethernet electrometer 100 can be reconfigured into a digital pattern generator for use in scientific applications. Ethernet electrometer 100 can also be reconfigured for use in I/O applications, control applications, security applications, lighting applications, camera applications pump applications, fan applications, home entertainment applications, etc.

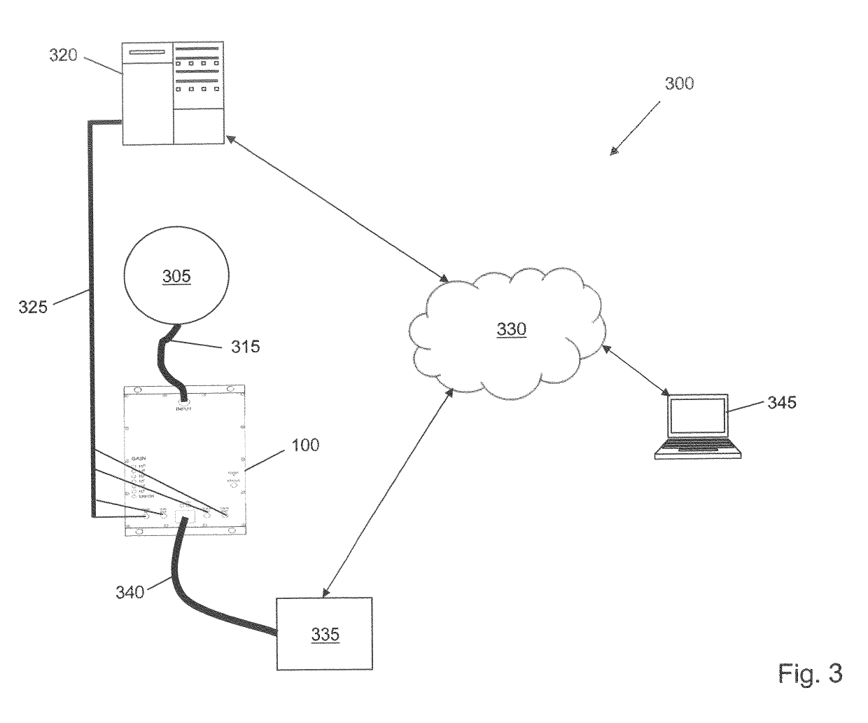

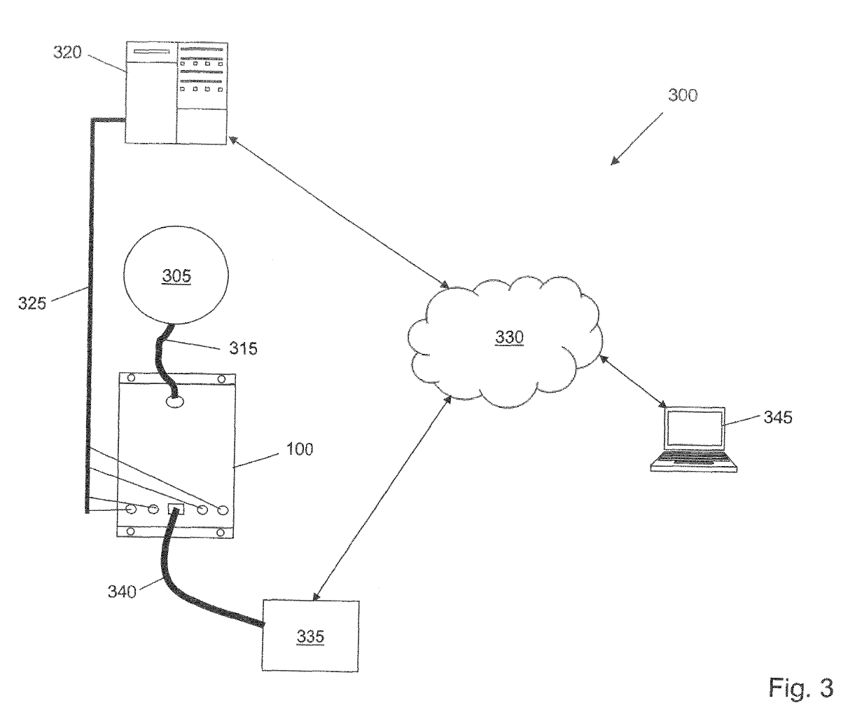

FIG. 3 depicts an Ethernet electrometer system 300 in accordance with an exemplary embodiment. Ethernet electrometer system 300 includes an analog signal source 305. Analog signal source 305 can be a current source, a voltage source, a radiation source, a light source, a pressure source, or any other type of source of an analog signal which is capable of being measured. As an example, analog signal source may be a current producing photodiode or ionization tube. Analog signals from analog signal source 305 can be conveyed to Ethernet electrometer 100 through an input line 315 as described with reference to FIGS. 1 and 2. Ethernet electrometer 100 can send and receive data to/from a local computer 320 through an input/output line 325. Input/output line 325 can be one or more conducting lines through which local computer 320 can monitor analog signal source 305 and/or provide command information to Ethernet electrometer 100. In an exemplary embodiment, local computer 320 can be located in the vicinity (i.e., within several thousand feet) of Ethernet electrometer 100. Local computer 320 can also be connected to a network 330 such that analog signal source 305 can be remotely monitored and/or such that Ethernet electrometer 100 can be remotely controlled. Network 330 can be a local area network (LAN), a wide area network (WAN) such as the Internet, a wireless communications network or any other type of network through which information can be transferred.

Ethernet electrometer 100 can be in electrical communication with an Ethernet hub 335 through an Ethernet cable 340. Ethernet hub 335 can be used to provide power over Ethernet (PoE) to Ethernet electrometer 100. Alternatively, PoE can be provided to Ethernet electrometer 100 by any other method known to those of skill in the art. Ethernet hub 335 can also be connected to network 330 such that Ethernet electrometer 100 can communicate with a remotely located user device 345. User device 345 can be a personal computer, a laptop computer, a cellular telephone a personal digital assistant, a portable gaming device, or any other type of computing device which is capable of communicating over network 330. In an alternative embodiment, Ethernet cable 340 may be directly or indirectly connected to local computer 320 such that information can be directly exchanged between local computer 320 and Ethernet electrometer 100. Local computer 320 can also be any type of computing device.

In an exemplary embodiment, the Ethernet electrometer described with reference to FIGS. 1-3 can be a compact, space saving device. The Ethernet electrometer combines a signal monitoring/measuring device with a web server, a communication interface, signal conditioning functionality, power over Ethernet, and processing functionality. As such, there is no need for a large power supply, crates, external processors, external signal conditioning devices, external communication devices, etc. As a result, Ethernet electrometer provides a compact, cost effective solution which replaces an entire room's worth of bulky electronics and support devices. Further, the Ethernet electrometer described herein can be used for a plurality of different purposes and is not limited to any specific application. For example, the Ethernet electrometer can be used for beam monitoring, scanning of cargo or personnel for suspected radiation, area radiation detection, integrated dose counting, and photon detection. The Ethernet electrometer can also be used for homeland defense applications such as sensor monitoring in subways, sports stadiums, airplanes, public buildings, etc. The Ethernet electrometer can also be integrated into virtually any existing monitoring or control system in homes, schools, factories, etc.

The foregoing description of exemplary embodiments has been presented for purposes of illustration and of description. It is not intended to be exhaustive or limiting with respect to the precise form disclosed, and modifications and variations are possible in light of the above teachings or may be acquired from practice of the disclosed embodiments. It is intended that the scope of the invention be defined by the claims appended hereto and their equivalents.

What is claimed is:

1. An electrometer comprising:
an input terminal adapted to receive an input signal;
an ethernet terminal adapted to receive an ethernet cable such that electrical power is provided to the ethernet terminal;
a web server in electrical communication with the ethernet terminal, wherein the web server is adapted to receive a command; and
a microcontroller in electrical communication with at least one of the ethernet terminal and the web server, wherein the microcontroller is adapted to execute the received command.

2. The electrometer of claim 1, wherein the received command is received from a network browser in communication with the web server through a network.

3. The electrometer of claim 1, wherein the input terminal is mounted on an interchangeable daughterboard, and further wherein the microcontroller comprises a program corresponding to the interchangeable daughterboard.

4. The electrometer of claim 3, wherein the interchangeable daughterboard further comprises an amplifier configured to amplify the received input signal.

5. The electrometer of claim 4, wherein the amplifier comprises at least ten thousand gain steps.

6. The electrometer of claim 1, wherein the received command comprises a sample rate setting, and further wherein the sample rate setting is within a range from approximately direct current to approximately one sample every 12.5 microseconds.

7. The electrometer of claim 1, wherein the received command comprises an amplifier setting, and further wherein the amplifier setting is within a range from approximately 10⁴ Volts/Amp to approximately 10¹¹ Volts/Amp.

8. The electrometer of claim 1, further comprising a 16-bit converter configured to convert the received input signal.

9. The electrometer of claim 1, further comprising a signal conditioning module adapted to implement analog filtering of the received input signal.

10. The electrometer of claim 9, wherein the signal conditioning module is further adapted to implement digital filtering of the received input signal.

11. The electrometer of claim 10, wherein the received command is related to at least one of an amount of the analog filtering performed on the received input signal and an amount of the digital filtering performed on the received input signal.

12. An electrometer comprising:
an interchangeable daughterboard comprising an input terminal adapted to receive an input signal; and
a motherboard in electrical communication with the interchangeable daughterboard and comprising
an ethernet terminal adapted to receive an ethernet cable through which information is received;
a web server in electrical communication with the ethernet terminal wherein the web server is adapted to receive a command; and
a microcontroller comprising a program corresponding to the interchangeable daughterboard, wherein the microcontroller is configured to execute the received command.

13. The electrometer of claim 12, wherein the interchangeable daughterboard further comprises an amplifier configured to amplify the received input signal.

14. The electrometer of claim 12, wherein the microcontroller is adapted to receive a second program corresponding to a second interchangeable daughterboard upon replacement of the interchangeable daughterboard with the second interchangeable daughterboard.

15. The electrometer of claim 14, wherein the second program is downloaded to the microcontroller through the web server.

16. The electrometer of claim 12, wherein electrical power is also received through the ethernet cable.

17. An electrometer system comprising:
an electrometer comprising
an input terminal adapted to receive an input signal;
an ethernet terminal adapted to receive an ethernet cable through which electrical power is received; and
a web server in electrical communication with the ethernet terminal wherein the web server is adapted to receive a command; and
a remote computer in communication with the web server, wherein the remote computer is adapted to provide the command to the web server.

18. The electrometer system of claim 17, wherein the remote computer is in communication with the web server through a network.

19. The electrometer system of claim 17, wherein the remote computer is in communication with the web server through the ethernet cable.

20. The electrometer system of claim 17, further comprising a local computer adapted to receive a representation of the received input signal through an output terminal of the electrometer.
